(19) United States
(12) Patent Application Publication
(10) Pub. No.: US 2026/0188929 A1
(43) Pub. Date: Jul. 2, 2026

(54) PLUG CONNECTOR AND BOARD-TO-BOARD CONNECTOR ASSEMBLY INCLUDING THE SAME

(71) Applicant: Molex, LLC, Lisle, IL (US)

(72) Inventor: Suk Min Kim, Ansan-si (KR)

(21) Appl. No.: 19/427,361

(22) Filed: Dec. 19, 2025

(30) Foreign Application Priority Data
Dec. 27, 2024 (KR) 10-2024-0198294

(51) Int. Cl. H01R 12/71; H01R 12/70; H01R 13/24; H01R 13/504

(52) U.S. Cl. CPC H01R 12/716; H01R 12/707; H01R 12/7082; H01R 13/2492; H01R 13/504

(57) ABSTRACT

A plug connector includes a plug body and plug terminals and a plug fitting nail which are coupled to the plug body. The plug body has a bottom portion, pairs of first wall portions extending in a width direction and second wall portions extending in a length direction. The plug fitting nail includes an upper cover disposed on an upper side of the first wall portion, an outer cover extending downwardly from an outer end of the upper cover in the length direction, a pair of arms extending inwardly from both ends of the outer cover in the width direction along the length direction, a pair of bases extending from a part of lower ends of the one pair of arms inwardly in the width direction in parallel with the bottom portion, respectively, and a pair of contact portions extending upwardly from the one pair of bases, respectively.

### TECHNICAL FIELD

The present disclosure relates to a plug connector and a board-to-board connector assembly (B-to-B connector) including the same.

### DESCRIPTION OF RELATED ART

As lightening and miniaturization of mobile electronic products continue, ensuring reliability of electrical connections and structural strength of board-to-board connectors is required. A board-to-board connector typically has a plurality of terminals and provides electrical connection between printed circuit boards (PCBs), and enables transmission of power and signals and mechanical coupling. A connector should be designed to ensure stable coupling between terminals while ensuring structural strength considering increased density of a circuit board and space constraints. In particular, connectors for mobile devices are required to ensure durability against vibrations and impacts as their sizes are miniaturized.

A connector may include a plug body which is formed of an insulator and has a sidewall in a rectangular frame shape, and one pair of reinforcing fitting nails (reinforcing metal fittings or metal fittings) coupled to both sides of the plug body. The reinforcing fitting nail prevents the plug body from being damaged when the connector is coupled to a counterpart connector or is subjected to external impact. The reinforcing fitting nail may also function as a power terminal or a high-current terminal, and it is referred to as a power nail. In this case, an elastic contact portion may further be provided on the reinforcing fitting nail to enhance electrical contact stability between the fitting nail and the counterpart connector.

A prior art document, Korean Patent Publication No. 10-2024-0066966, discloses an elastic contact portion provided in a reinforcing fitting nail of a plug connector. The related-art reinforcing fitting nail includes a main upper plate, an inner wall protection portion extending downwardly from an inner end of the main upper plate, a bottom plate portion horizontally extending from the inner wall protection portion, and one pair of elastic contact portions extending upwardly from the bottom plate portion. When the connector is coupled to a counterpart connector with the reinforcing fitting nail having such a shape, impact applied to a connection between the main upper plate and the inner wall protection portion of the reinforcing fitting nail may be directly transmitted to the elastic contact portion. Specifically, an island portion of a receptacle connector may be directly brought into contact with the main upper plate or the inner wall protection portion of the reinforcing fitting nail of the plug connector, causing impact during assembly. To this end, the elastic contact portion of the reinforcing fitting nail is deformed or has a gap, causing unstable electrical contact with a counterpart connector. Accordingly, there is a need for further ensuring stability of electrical contact between the elastic contact portion of the connector and the counterpart connector.

Meanwhile, when a connector provided with a plurality of terminals and one pair of reinforcing fitting nails is made by insert injection molding, there may be a problem that a specific portion of the reinforcing fitting nail is not sufficiently filled with a liquid resin due to a small and complex shape of the reinforcing fitting nail. Accordingly, there is a need for a design of a reinforcing fitting nail capable of ensuring flow of an injection resin within a mold.

### SUMMARY

Embodiments of the present disclosure are to solve the above problems of the related art.

An object of embodiments of the present disclosure is to increase robustness on a reinforcing fitting nail and stability of electrical connection of an elastic contact portion when a connector is assembled or is subjected to external impact. In addition, an object of embodiments of the present disclosure is to provide a connector provided with a reinforcing fitting nail capable of ensuring smooth flow of a liquid resin during insert injection molding.

A plug connector according to an embodiment may include: a plug body which includes a bottom portion, one pair of first wall portions extending in a width direction WD, and one pair of second wall portions extending in a length direction LD; a plug fitting nail which is coupled to the plug body; and a plurality of plug terminals which are coupled to the plug body. The plug fitting nail may include: a first upper cover which is disposed on an upper side of the first wall portion; a first outer cover which extends downwardly from an outer end of the first upper cover in the length direction; one pair of arms which extend inwardly from both ends of the first outer cover in the width direction along the length direction; one pair of bases which extend from a part of lower ends of the one pair of arms inwardly in the width direction in parallel with the bottom portion, respectively; and one pair of contact portions which extend upwardly from the one pair of bases, respectively.

In an embodiment, the one pair of bases may include: one pair of first portions which extend inwardly from the one pair of arms along the width direction, respectively; and one pair of second portions which extend inwardly from the one pair of first portions along the length direction, respectively, and the one pair of contact portions may extend upwardly from outer ends of the one pair of second portions in the width direction, respectively.

In an embodiment, the one pair of first portions may extend from the one pair of arms in a direction close to each other, respectively, and the one pair of second portions may extend in parallel with each other.

In an embodiment, the one pair of bases may be spaced apart from each other in the width direction to define a gap that extends between the one pair of bases in the length direction.

In an embodiment, the plug fitting nail may further include a first mounting portion which extends from a lower end of the first outer cover, and at least a part of the first mounting portion may be recessed upwardly from a bottom surface of the first mounting portion to define a first opening penetrating through inner and outer sides of the first mounting portion in the length direction.

In an embodiment, the plug fitting nail may further include a first inner cover which extends downwardly from an inner end of the first upper cover in the length direction.

According to an embodiment, the plug fitting nail may further include: one pair of second upper covers which extend from both ends of the first upper cover in the width direction to be disposed on an upper side of a part of the second wall portion; and one pair of second outer covers which extend downwardly from respective outer ends of the second upper covers in the width direction.

In an embodiment, the plug fitting nail may further include one pair of second mounting portions which extend from lower ends of the one pair of second outer covers, and at least a part of the second mounting portion may be recessed upwardly from a bottom surface of the second mounting portion to define a second opening penetrating through inner and outer sides of the second mounting portion in the width direction.

In an embodiment, the one pair of arms may be disposed to overlap the one pair of second outer covers in the width direction.

In an embodiment, the plug fitting nail may further include one pair of second inner covers which extend downwardly from respective inner ends of the one pair of second upper covers in the width direction.

In an embodiment, the plug fitting nail may further include a third inner cover configured to extend downwardly from an inner corner between the first upper cover and the second upper cover to cover a corner between the first wall portion and the second wall portion at least in part.

A connector assembly according to an embodiment includes: a plug connector of any one of the above-described embodiments; and a receptacle connector mating the plug connector.

According to embodiments of the present disclosure, since the elastic contact portion of the reinforcing fitting nail of the connector is not directly connected to a main upper plate, robustness on the elastic contact portion and stability of electrical connection may be ensured during assembly or when external impact is applied. In addition, according to embodiments of the present disclosure, there is provided a connector with high quality provided with a reinforcing fitting nail that ensures smooth flow of a liquid resin inside and around the reinforcing fitting nail when insert injection molding is performed.

### BRIEF DESCRIPTION OF THE DRAWINGS

FIG. 1 is a perspective view of a connector assembly according to an embodiment.

FIG. 2A is a perspective view of a plug connector according to an embodiment.

FIG. 2B is an exploded perspective view of the plug connector.

FIG. 2C is an exploded perspective view of a receptacle connector.

FIG. 2D is a bottom view of the receptacle connector.

FIG. 2E is a cross-sectional view taken on line L1-L1′ of FIG. 1, illustrating the connector assembly.

FIG. 2F is a cross-sectional view taken on line L2-L2′ of FIG. 1, illustrating the connector assembly.

FIG. 3 is a top view of the plug connector according to an embodiment.

FIG. 4 is a cross-sectional view taken on line I-I′ of FIG. 2A, illustrating the plug connector.

FIG. 5 is a perspective view of a plug fitting nail according to an embodiment.

FIG. 6 is a perspective view of the plug fitting nail as viewed from a different angle from that of FIG. 5.

FIG. 7 is a bottom view of the plug fitting nail of FIG. 5.

FIG. 8 is a cross-sectional view taken on line II-II′ of FIG. 3, illustrating the plug connector.

FIG. 9 is a cross-sectional view taken on line III-III′ of FIG. 3, illustrating the plug connector.

FIG. 10 is a perspective view of a plug fitting nail according to another embodiment.

FIG. 11 is a top view of the fitting nail of FIG. 10.

FIG. 12 is a cross-sectional view taken on line IV-IV′ of FIG. 3, illustrating the plug connector.

FIG. 13 is a view illustrating a plug connector according to another embodiment.

FIG. 14 is a view illustrating a plug fitting nail according to still another embodiment.

### DETAILED DESCRIPTION

Embodiments of the present disclosure are illustrated for the purpose of explaining the technical concept of the present disclosure. The right scope of the present disclosure is not limited to embodiments suggested hereinbelow or detailed descriptions of these embodiments.

All technical terms and scientific terms used in the present disclosure have meanings normally understood by those skilled in the art to which the present disclosure belongs unless otherwise defined. All terms used in the present disclosure are selected for the purpose of explaining the present disclosure more clearly and are not selected to limit the right scope of the present disclosure.

It should be understood that the terms “comprise,” “include,” and “have” used in the present disclosure are open-ended terms that have possibility of including other embodiments unless phrases or sentences including corresponding expressions indicate otherwise.

The singular forms used in the present disclosure may include the plural forms as well unless the context clearly indicates otherwise, and this is equally applied to the singular forms described in the claims.

Such terms “first” and “second” used in the present disclosure are used to simply distinguish a plurality of components from one another, and do not limit the components in the aspect of order or importance.

It should be understood that, when an element is referred to as “connected” or “is coupled” to another element in the present disclosure, it means that the element may be directly connected or coupled to another element or may be connected or coupled to another element via still another element.

Directional terms such as “upward” and “above” used in the present disclosure are based on a direction in which an upper cover of a fitting nail is located with respect to a bottom portion of the fitting nail in the accompanying drawings, and directional terms such as “downward” and “below” mean an opposite direction. A plug connector or a fitting nail illustrated in the accompanying drawings may be oriented differently, and the directional terms may be interpreted accordingly.

Hereinafter, embodiments of the present disclosure will be described with reference to the accompanying drawings. In the accompanying drawings, the same reference numerals are used for the same or corresponding components. Further, in explaining the following embodiments, a redundant explanation of the same or corresponding components may be omitted. However, even when description of a component is omitted, it is not intended that the component is not included in a certain embodiment.

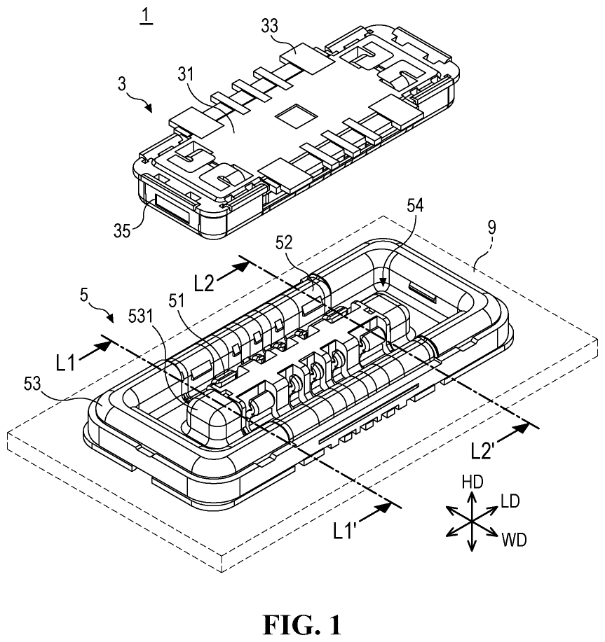

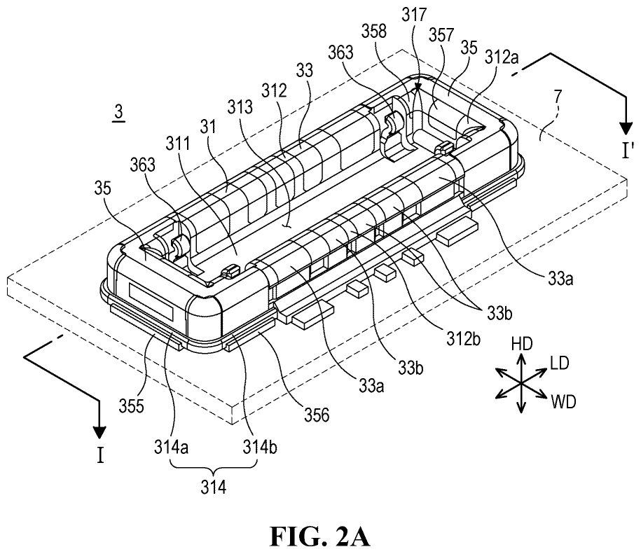

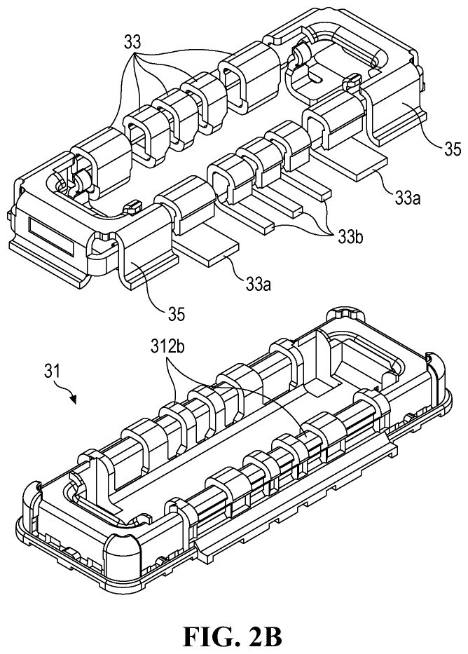

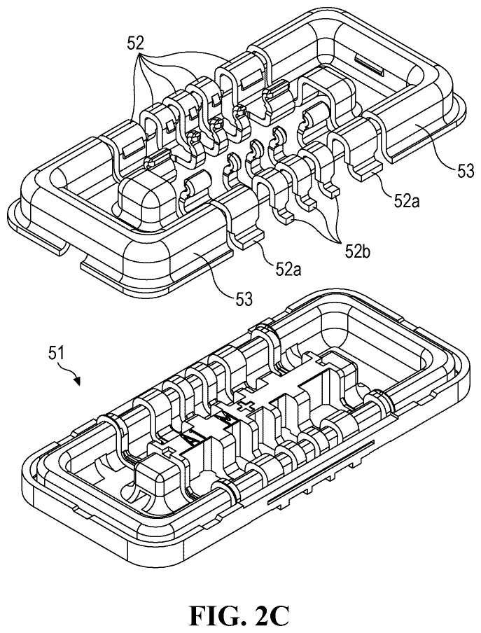

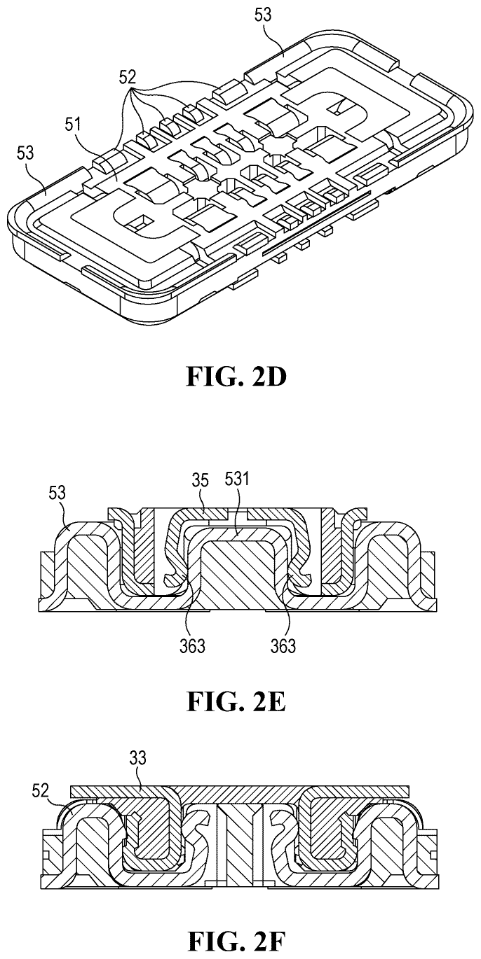

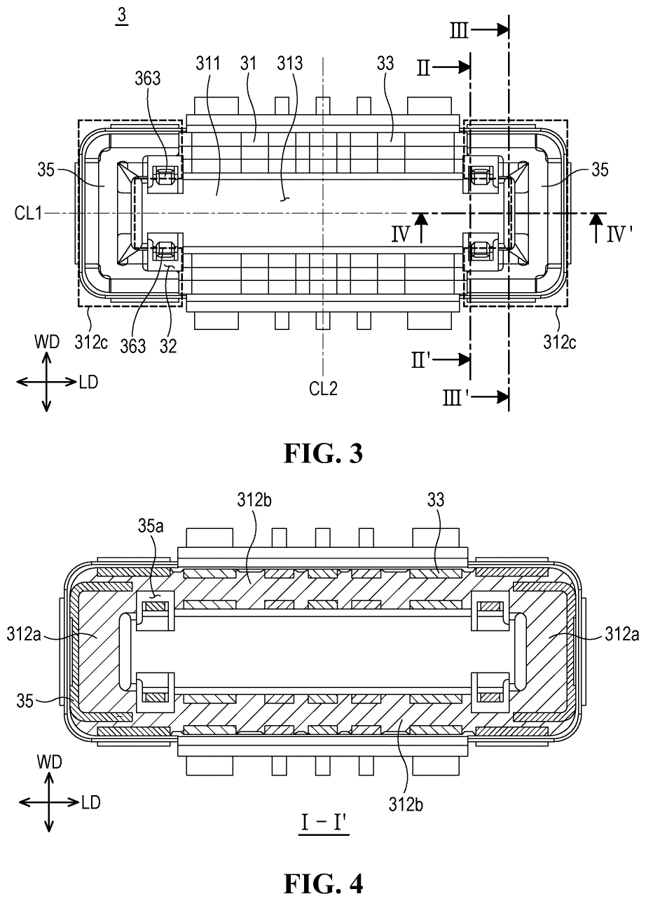

FIG. 1 is a perspective view of a connector assembly 1 according to an embodiment. FIG. 2A is a perspective view of a plug connector 3 according to an embodiment. FIG. 2B is an exploded perspective view of the plug connector 3. FIG. 2C is an exploded perspective view of a receptacle connector 5. FIG. 2D is a bottom view of the receptacle connector 5. FIG. 2E is a cross-sectional view taken on line L1-L1′ of FIG. 1, illustrating the connector assembly 1. FIG. 2F is a cross-sectional view taken on line L2-L2′ of FIG. 1, illustrating the connector assembly 1. FIG. 3 is a top view of the plug connector 3 according to an embodiment. FIG. 4 is a cross-sectional view taken on line I-I′ of FIG. 2A, illustrating the plug connector 3.

Referring to FIGS. 1 and 2A, the connector assembly 1 includes the plug connector 3 and the receptacle connector 5 as a counterpart connector of the plug connector 3. The plug connector 3 and the receptacle connector 5 may be engaged with each other, thereby being electrically connected to each other and exchanging electrical signals or power with each other. The plug connector 3 and the receptacle connector 5 may be mounted on a first substrate 7 and a second substrate 9, respectively, and may be coupled to each other, such that electrical signals or power is exchanged between the second substrate 9 and the first substrate 7.

In the present disclosure, a width direction WD refers to a direction in which the short side of the connector assembly 1 extends, or a direction substantially identical thereto. In addition, a length direction LD refers to a direction in which the long side of the connector assembly 1 extends, or a direction substantially identical thereto. In addition, a height direction HD refers to a direction in which the receptacle connector 5 and the plug connector 3 are assembled with each other or a direction substantially identical thereto. In the present disclosure, an inner side refers to a side that is close to the center of the plug connector 3, and an outer side refers to a side that is far away from the center of the plug connector 3. For example, referring to FIG. 3, an inner side in the width direction WD refers to a side that is close to the center line CL1 of the width direction WD of the plug connector 3, and an outer side in the width direction WD refers to a side that is far away from the center line CL1. In addition, an inner side in the length direction LD refers to a side that is close to the center line CL2 of the length direction LD of the plug connector 3, and an outer side in the length direction LD refers to a side that is far away from the center line CL2.

Referring to FIGS. 2A to 4, the plug connector 3 includes a plug body 31 extending in the length direction LD. The plug body 31 includes a bottom portion 311 and a wall portion 312 protruding from the edge of the bottom portion 311 in the height direction HD. The wall portion 312 is provided in the form of a rectangular frame. The wall portion 312 includes one pair of first wall portions 312a extending in the width direction WD, and one pair of second wall portions 312b extending in the length direction LD. The plug connector 3 includes a recess portion 313 surrounded by the wall portion 312. Referring to FIG. 1, an island portion 54 of the receptacle connector 5 is accommodated in the recess portion 313.

Referring to FIG. 3, U-shaped portions at both ends of the wall portion 312 in the length direction LD may be referred to as plug end walls 312c. For example, the plug end wall 312c may refer to the first wall portion 312a and portions (a part of the second wall portion 312b) extending from both ends of the first wall portion 312a in parallel in the length direction LD.

The plug connector 3 includes a plug terminal 33 and a plug fitting nail 35 which are coupled to the plug body 31. A plurality of plug terminals 33 are arranged on the one pair of second wall portions 312b along the length direction LD.

The plurality of plug terminals 33 or a plurality of receptacle terminals 52 may be configured as signal terminals or auxiliary power terminals. Referring to FIGS. 2A and 2B, the plug terminal 33 may include first plug terminals 33a which are disposed on the second wall portion 312b at both sides in the length direction LD, and second plug terminals 33b which are disposed between the first plug terminals 33a. The first plug terminal 33a may function as an auxiliary power terminal, and the second plug terminal 33b may function as a signal terminal. The first plug terminal 33a may have a width in the length direction LD that is wider than that of the second plug terminal 33b. Referring to FIGS. 2C and 2D, the receptacle terminal 52 may include first receptacle terminals 52a which are disposed on a receptacle body 51 at both sides in the length direction LD, and second receptacle terminals 52b which are disposed between the first receptacle terminals 52a. The first receptacle terminal 52a may function as an auxiliary power terminal, and the second receptacle terminal 52b may function as a signal terminal. The first receptacle terminal 52a may have a width in the length direction LD that is wider than that of the second receptacle terminal 52b.

Referring to FIG. 2E, when the plug connector 3 is coupled to the receptacle connector 5, the plug fitting nail 35 comes into contact with a receptacle fitting nail 53. In this case, the island portion 531 of the receptacle fitting nail 53 is inserted between one pair of contact portions 363. Referring to FIG. 2F, when the plug connector 3 is coupled to the receptacle connector 5, the plug terminal 33 comes into contact with the receptacle terminal 52.

Referring to FIGS. 1 and 2A, the plug terminal 33 has one end connected to the first substrate 7, and the other end coming into contact with the receptacle terminal 52 when being connected to the receptacle connector 5. The plug terminal 33 may be formed by pressing and bending a plate of a metallic material having excellent conductivity, and may be integrally manufactured with the plug body 31 by overmolding.

The plug fitting nail 35 may be disposed at both ends of the plug body 31 to reinforce rigidity of the plug body 31. Referring to FIG. 2A, the plug fitting nail 35 may be configured to surround at least a part of the plug end wall 312c, and may protect the plug end wall 312c. The plug fitting nail 35 may be soldered to the first substrate 7 to fix the plug connector 3 to the first substrate 7. The plug fitting nail 35 may come into contact with the receptacle fitting nail 53 when being connected to the receptacle connector 5. The plug fitting nail 35 may be formed by pressing and/or bending a plate of a metallic material. The plug fitting nail 35 may be integrally manufactured with the plug body 31 by overmolding.

The plug terminal 33 and the plug fitting nail 35, which are typically manufactured with a copper alloy for electrical conductivity, may have portions electrically connected to the first substrate 7 and plated with gold (Au) to enhance conductivity. In addition, the plug terminal 33 and the plug fitting nail 35 may have portions for solder wicking prevention extended from the portions electrically connected to the first substrate 7 and plated with nickel (Ni) to enhance anti-corrosion.

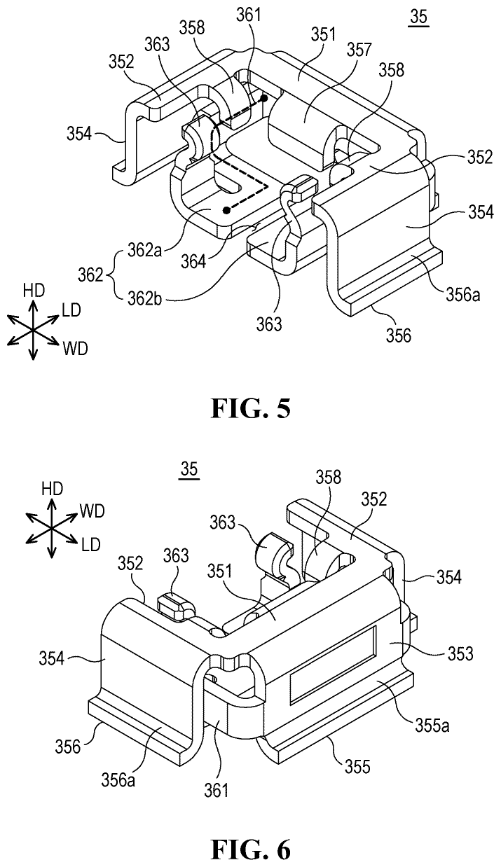

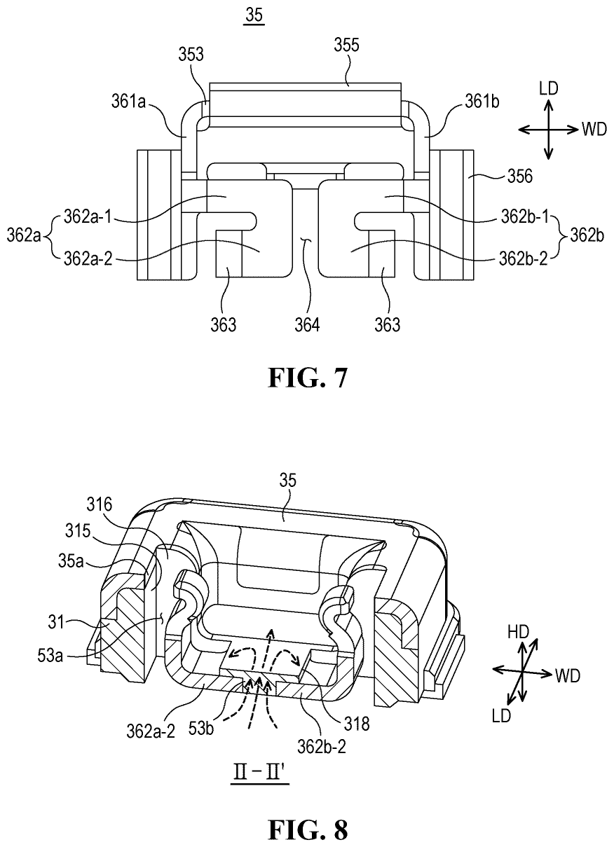

FIG. 5 is a perspective view of the plug fitting nail 35 according to an embodiment. FIG. 6 is a perspective view of the plug fitting nail 35 as viewed from a different angle from that of FIG. 5. FIG. 7 is a bottom view of the plug fitting nail 35 of FIG. 5. FIG. 8 is a cross-sectional view taken on line II-II′ of FIG. 3, illustrating the plug connector 3.

Referring to FIGS. 5 to 7, the plug fitting nail 35 includes a first upper cover 351 disposed on an upper side of the first wall portion 312a, and one pair of second upper covers 352 extending from both ends of the first upper cover 351 to be disposed on an upper side of a part of the second wall portion 312b. The first upper cover 351 and the one pair of second upper covers 352 may have a U-shape when the plug fitting nail 35 is viewed from above or below.

The plug fitting nail 35 includes a first outer cover 353 extending downwardly from an outer end of the first upper cover 351 in the length direction LD. The first outer cover 353 is configured to cover an outer surface of the first wall portion 312a. The outer surface of the first upper cover 351 and the outer surface of the first outer cover 353 may smoothly be connected to each other with a curved surface.

The plug fitting nail 35 includes one pair of second outer covers 354 extending downwardly from respective outer ends of the second upper covers 352 in the width direction WD. The second outer cover 354 is configured to cover a part of the outer surface of the second wall portion 312b. The outer surface of the first upper cover 351 and the outer surface of the first outer cover 353 (or the second outer cover 354) may smoothly be connected to each other with a curved surface.

The plug fitting nail 35 may further include a first mounting portion 355 extending from a lower end of the first outer cover 353. The first mounting portion 355 may extend outwardly from the lower end of the first outer cover 353 along the length direction LD. The plug fitting nail 35 may further include a second mounting portion 356 extending from a lower end of the second outer cover 354. The second mounting portion 356 may extend outwardly from the lower end of the second outer cover 354 along the width direction WD. The first mounting portion 355 and the second mounting portion 356 provide a contact surface with the first substrate 7, and the contact surface and the first substrate 7 are coupled to each other by soldering. The outer surface of the first mounting portion 355 (or the second mounting portion 356) and the outer surface of the second outer cover 354 may smoothly be connected to each other with a curved surface.

When the plug fitting nail 35 is soldered to the first substrate 7 through the first mounting portion 355 and the second mounting portion 356, a solder wicking phenomenon that the solder spreads along the surfaces of the first outer cover 353 and the second outer cover 354 may occur. Referring to FIG. 2A, the plug body 31 may include a solder barrier portion 314 disposed between the outer cover 353, 354, and the mounting portion 355, 356 to prevent such solder wicking. For example, referring to FIG. 6, a corer 355a disposed between the first outer cover 353 and the first mounting portion 355 may be covered by a first solder barrier portion 314a. The first solder barrier portion 314a may prevent the solder from spreading toward the first outer cover 353 when the first mounting portion 355 is soldered to the first substrate 7. In addition, a corer 356a disposed between the second outer cover 354 and the second mounting portion 356 may be covered by a second solder barrier portion 314b. The second solder barrier portion 314b may prevent the solder from going upward along the second outer cover 354 when the second mounting portion 356 is soldered to the first substrate 7.

Referring to FIG. 5, the plug fitting nail 35 may further include a first inner cover 357 extending downwardly from an inner end of the first upper cover 351 in the length direction LD. The plug fitting nail 35 may further include second inner covers 358 extending downwardly from respective inner ends of the one pair of second upper covers 352 in the width direction WD.

Referring to FIGS. 5 and 6, the plug fitting nail 35 includes one pair of arms 361 extending from both ends of the first outer cover 353 in the width direction WD along the length direction LD. The one pair of arms 361 are disposed inside the one pair of the second outer cover 354 in the width direction WD.

Referring to FIG. 7, the one pair of arms 361 includes a first arm 361a and a second arm 361b. The first arm 361a extends inwardly from one end of the first outer cover 353 in the width direction WD along the length direction LD. The second arm 361b extends inwardly from the other end of the first outer cover 353 in the width direction WD along the length direction LD. The first arm 361a and the second arm 361b extend in parallel with each other while facing each other in the width direction WD. The surface of the first arm 361a (or the second arm 361b) and the surface of the first outer cover 353 may smoothly be connected to each other with a curved surface.

Referring to FIGS. 3 and 5, the plug fitting nail 35 includes one pair of bases 362 extending from parts of lower ends of the one pair of arms 361 inwardly in the width direction WD in parallel with the bottom portion 311 of the plug body 31, respectively. Mechanical strength of the bottom portion 311 may be enhanced due to the one pair of bases 362 which are parallel to the bottom portion 311.

The one pair of bases 362 includes a first base 362a and a second base 362b. T first base 362a and the second base 362b extend from a part of the lower end of the first arm 361a and a part of the lower end of the second arm 361b, respectively.

Referring to FIG. 7, the one pair of bases 362 includes one pair of first portions 362a-1, 362b-1 extending inwardly from the one pair of arms 361 along the width direction WD, respectively, and one pair of second portions 362a-2, 362b-2 extending inwardly from the one pair of first portions 362a-1, 362b-1 along the length direction LD, respectively. The one pair of first portions 362c may extend from the one pair of arms 361 in a direction close to each other, respectively. The one pair of second portions 362a-2, 362b-2 may extend in parallel with each other.

The plug fitting nail 35 may function as a power terminal, a high-current terminal or a ground terminal, and, in order to enhance electrical contact stability between the fitting nail and a counterpart connector, the plug fitting nail 34 includes one pair of contact portions 363 extending upwardly from the one pair of bases 362, respectively. For example, the one pair of contact portions 363 may extend upwardly from outer ends of the one pair of second portions 362a-2, 362b-2 in the width direction WD, respectively. The one pair of contact portions 363 are disposed more inward in the width direction WD than the one pair of arms 361.

Referring to FIG. 1, the contact portion 363 of the plug fitting nail 35 is configured to be press-fitted into the island portion 531 of the corresponding receptacle fitting nail 53, thereby pressing the island portion 531 in the width direction WD. When the contact portion 363 is coupled to the island portion 531, the one pair of contact portions 363 come into contact with both sides of the island portion 531 in the width direction WD.

The contact portion 363 of the fitting nail is connected to the first upper cover 351 through the bottom portion 311, the arm 361, and the first outer cover 353. The contact portion 363 is provided in the shape as described above, such that, even when impact is applied to the first upper cover 351 and the first inner cover 357 of the plug fitting nail 35 in the process of coupling the plug connector 3 and the receptacle connector 5, the impact is not directly applied to the contact portion 363, and accordingly, electrical contact between the contact portion 363 and the counterpart connector is prevented from being unstable due to deformation of the contact portion 363.

When the island portion 531 of the receptacle fitting nail 53 of the receptacle connector 5 is accommodated between the one pair of contact portions 363, the one pair of contact portions 363 may be deformed or moved to have a gap therebetween. A restoring force of the contact portion 363 that is made when the gap is created makes the electrical contact between the contact portion 363 and the island portion 531 stable. Meanwhile, the plug connector 3 is configured to allow deformation and movement when the contact portion 363 is coupled with a counterpart object. Referring to FIGS. 3 and 8, the plug connector 3 may define an avoidance space 32. The contact portion 363 may be deformed or move without colliding with the plug body 31 within the avoidance space 32. Referring to FIG. 8, the avoidance space 32 may be defined by surfaces 315, 316 of the plug body 31 and a surface 35a of the plug fitting nail 35.

Referring to FIGS. 5 and 7, the one pair of bases 362 may be spaced apart from each other in the width direction WD, thereby defining a gap 364 extending in the length direction LD between the one pair of bases 362. That is, the gap 364 exists between the first base 362a and the second base 362b. The one pair of second portions 362a-2, 362b-2 may extend in parallel with each other, being spaced apart from each other in the width direction WD.

When the plug connector 3 is manufactured by positioning the plug terminal 33 and the plug fitting nail 35 in a mold and then injecting a liquid resin into the mold to form the plug body 31 when it is solidified, the liquid resin is typically supplied to the center of the plug connector 3 and spreads toward both ends in the length direction LD from the center. Referring to FIG. 8, in the process of forming the plug body 31, the liquid resin may flow through the gap 364 between the one pair of bases 362. Since there is the gap 364 formed in the base 362 in the length direction LD, the flow of the liquid resin in the length direction LD is facilitated.

As the flow of the liquid resin is facilitated, the liquid resin may well fill the inside of the mold without having to increase the pressure for injecting the liquid resin into the mold, and the plug body 31 with better quality may be formed. For example, a portion that occupies a relatively small volume while being positioned at both ends of the plug connector 3 in the length direction LD, such as the solder barrier portion 314 of FIG. 2A, may be formed satisfactorily. Further, referring to FIG. 8, a portion 318 of the plug body 31 may cover the second portion 362a-2, 362b-2 at least in part, and the liquid resin may well flow into the corresponding portion 318 through the gap 364 of the base 362.

Referring to the cross-sectional view of FIG. 8, the cross-sectional area of the plug body 31 is reduced due to the avoidance space 53a, thereby narrowing a passage through which the liquid resin should pass to spread toward the end in the length direction LD. However, the gap 364 existing between the one pair of bases 362 compensates for the reduction in the cross-sectional area of the passage caused by the avoidance space 53a, thereby enhancing the flow of the liquid resin.

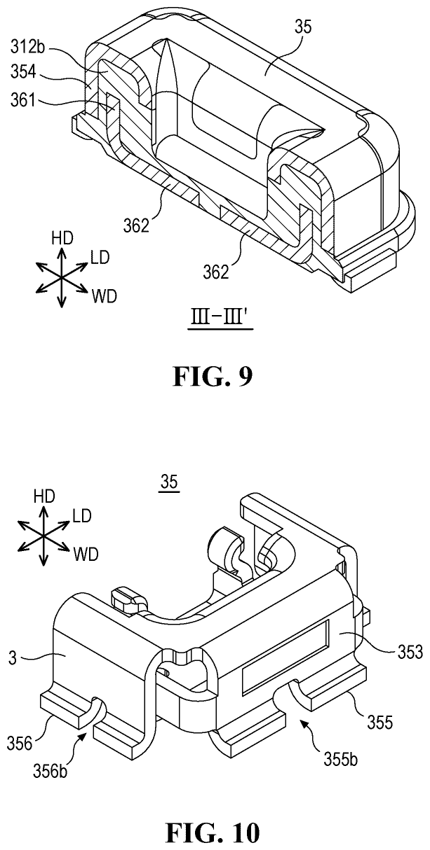

FIG. 9 is a cross-sectional view taken on line III-III′ of FIG. 3, illustrating the plug connector 3. Referring to FIG. 9, the arm 361 may be buried inside the second wall portion 312b. The one pair of arms 361 may be disposed to overlap the second outer cover 354 in the width direction WD. The outside of the second wall portion 312b is covered by the second outer cover 354, and the arm 361 is disposed inside a part of the second wall portion 312b, so that the strength of the second wall portion 312b is reinforced.

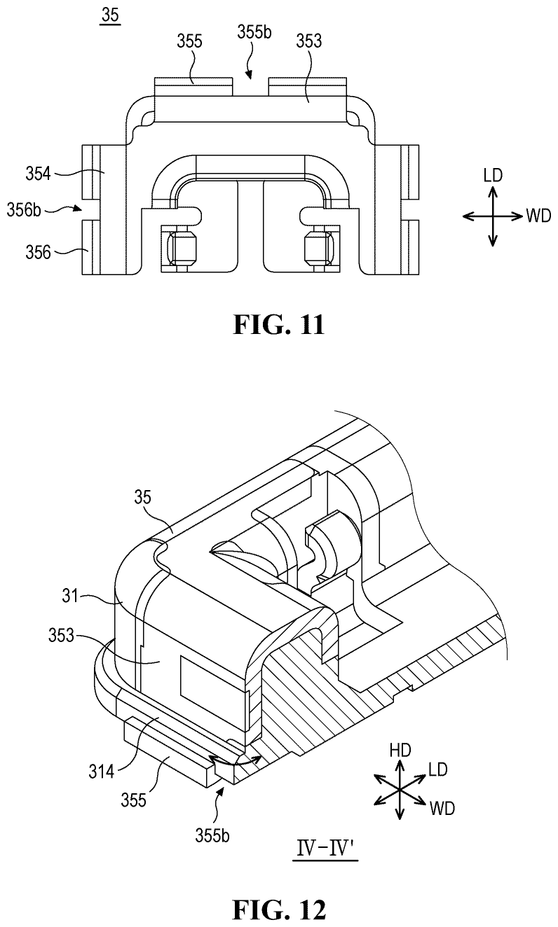

FIG. 10 is a perspective view of a plug fitting nail 35 according to another embodiment. FIG. 11 is a top view of the fitting nail of FIG. 10. FIG. 12 is a cross-sectional view taken on line IV-IV′ of FIG. 3, illustrating the plug connector 3.

Referring to FIGS. 10 and 11, at least a part of the first mounting portion 355 may be recessed upwardly from the bottom surface of the first mounting portion 355 to define a first opening 355b penetrating through the inner and outer sides of the first mounting portion 355 in the length direction LD. At least a part of the second mounting portion 356 may be recessed upwardly from the bottom surface of the second mounting portion 356 to define a second opening 356b penetrating through the inner and outer sides of the second mounting portion 356 in the width direction WD.

Referring to FIG. 12, the resin in the first outer cover 353 is connected to the solder barrier portion 314 through the first opening 355b. The solder barrier portion 314 occupies a relatively narrow volume, and the liquid resin should permeate a narrow space to form such a solder barrier portion 314. Since the liquid resin inside the first outer cover 353 escapes to the outside of the first outer cover 353 through the first opening 355b, the solder barrier portion 314 may be formed satisfactorily. The enhancement of the flow of the resin through the first opening 355b as described above is equally applied to the second opening 356b.

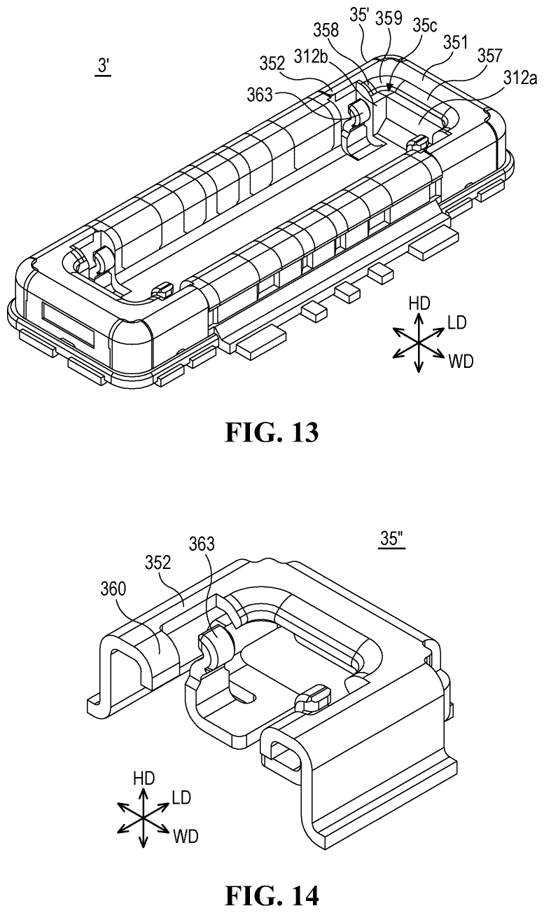

FIG. 13 is a view illustrating a plug connector 3′ according to another embodiment. FIG. 14 is a view illustrating a plug fitting nail 35′ according to another embodiment.

Referring to FIG. 13, the plug fitting nail 35′ may further include a third inner cover 359 extending downwardly from an inner corner 35c between the first upper cover 351 and the second upper cover 352. The third inner cover 359 is configured to cover a corner between the first wall portion 312a and the second wall portion 312b (for example, the corner 317 of FIG. 2A) at least in part. The plug fitting nail 35′ is rounded in a semi-drawing method in order to form the third inner cover 359. The drawing process refers to a process of seating a metal sheet on a die with a groove and pressing the metal sheet with a punch that has a shape corresponding to the groove into a solid object with depth. For example, the metal sheet may be drawn through a circular punch to have a cup-like shape. A drawing process in which a drawing depth is relatively large is referred to as deep drawing, while a drawing process in which a drawing depth is relatively small is referred to as semi-drawing. Curved surfaces that are seamlessly and continuously connected to each other may be formed by using semi-drawing. The plug fitting nail 35′ is manufactured by using one flat sheet having a thin thickness as a material and bending portions laid out on the sheet in a specific sequence. Prior to forming the third inner cover 359 by semi-drawing, a filling portion positioned on the same plane as the first upper cover 351 and the second upper cover 352 is provided between the first upper cover 351 and the second upper cover 352. When such a filling portion is rounded by applying pressure, the filling portion is deformed to be inclined downwardly and to be stretched in a curved shape between the first inner cover 357 and the second inner cover 358, thereby being molded into the third inner cover 359.

When the plug connector 3 is assembled with the receptacle connector 5, the third inner cover 359 may prevent the inner corner 35c of the plug connector 3 from being deformed or damaged by impact or the like.

Referring to FIG. 14, the plug fitting nail 35″ may include a fourth inner cover 360 extending downwardly from an inner edge of the second upper cover 352, and disposed more inward in the length direction LD than the contact portion 363. The fourth inner cover 360 may serve to protect the contact portion 363.

Although the technical concept of the present disclosure has been described through some embodiments described above and examples illustrated in the accompanying drawings, it should be noted that various substitutions, modifications, and changes can be made without departing from the technical concept and the scope of the present disclosure that can be understood by those skilled in the art to which the present disclosure belongs. In addition, the substitutions, modification, and changes should be deemed to belong to the claims attached hereto.

1. A plug connector comprising:
a plug body including a bottom portion, one pair of first wall portions extending in a width direction, and one pair of second wall portions extending in a length direction;
a plug fitting nail coupled to the plug body and including:
a first upper cover disposed on an upper side of the first wall portion. a first outer cover extending downwardly from an outer end of the first upper cover in the length direction,
one pair of arms extending inwardly from both ends of the first outer cover in the width direction along the length direction,
one pair of bases extending from a part of lower ends of the one pair of arms inwardly in the width direction in parallel with the bottom portion, respectively, and
one pair of contact portions extending upwardly from the one pair of bases, respectively; and
a plurality of plug terminals coupled to the plug body.

2. A connector assembly comprising:
the plug connector of claim 1; and
a receptacle connector mating the plug connector.

3. The plug connector of claim 1, wherein the one pair of bases comprise:
one pair of first portions extending inwardly from the one pair of arms along the width direction, respectively,
one pair of second portions extending inwardly from the one pair of first portions along the length direction, respectively, and
wherein the one pair of contact portions extend upwardly from outer ends of the one pair of second portions in the width direction, respectively.

4. A connector assembly comprising:
the plug connector of claim 3; and
a receptacle connector mating the plug connector.

5. The plug connector of claim 3, wherein the one pair of first portions extend from the one pair of arms in a direction close to each other, respectively, and the one pair of second portions extend in parallel with each other.

6. The plug connector of claim 1, wherein the one pair of bases are spaced apart from each other in the width direction to define a gap that extends between the one pair of bases in the length direction.

7. A connector assembly comprising:
the plug connector of claim 6; and
a receptacle connector mating the plug connector.

8. The plug connector of claim 1, wherein the plug fitting nail further comprises a first mounting portion extending from a lower end of the first outer cover, and at least a part of the first mounting portion is recessed upwardly from a bottom surface of the first mounting portion to define a first opening penetrating through inner and outer sides of the first mounting portion in the length direction.

9. A connector assembly comprising:
the plug connector of claim 8; and
a receptacle connector mating the plug connector.

10. The plug connector of claim 1, wherein the plug fitting nail further comprises a first inner cover extending downwardly from an inner end of the first upper cover in the length direction.

11. A connector assembly comprising:
the plug connector of claim 10; and
a receptacle connector mating the plug connector.

12. The plug connector of claim 1, wherein the plug fitting nail further comprises:
one pair of second upper covers extending from both ends of the first upper cover in the width direction to be disposed on an upper side of a part of the second wall portion; and
one pair of second outer covers extending downwardly from respective outer ends of the second upper covers in the width direction.

13. A connector assembly comprising:
the plug connector of claim 12; and
a receptacle connector mating the plug connector.

14. The plug connector of claim 12, wherein the plug fitting nail further comprises one pair of second mounting portions extending from lower ends of the one pair of second outer covers, and at least a part of the second mounting portion is recessed upwardly from a bottom surface of the second mounting portion to define a second opening penetrating through inner and outer sides of the second mounting portion in the width direction.

15. A connector assembly comprising:
the plug connector of claim 14; and
a receptacle connector mating the plug connector.

16. The plug connector of claim 12, wherein the one pair of arms are disposed to overlap the one pair of second outer covers in the width direction.

17. The plug connector of claim 12, wherein the plug fitting nail further comprises one pair of second inner covers extending downwardly from respective inner ends of the one pair of second upper covers in the width direction.

18. A connector assembly comprising:
the plug connector of claim 17; and
a receptacle connector mating the plug connector.

19. The plug connector of claim 12, wherein the plug fitting nail further comprises a third inner cover configured to extend downwardly from an inner corner between the first upper cover and the second upper cover to cover a corner between the first wall portion and the second wall portion at least in part.

20. A connector assembly comprising:
the plug connector of claim 19; and
a receptacle connector mating the plug connector.
